(19) United States
(12) Patent Application Publication
(10) Pub. No.: US 2008/0132020 A1
(43) Pub. Date: Jun. 5, 2008

(54) Method of forming silicon nano crystals and method of manufacturing memory devices having the same

(76) Inventors: Young-kwan Cha, Yongin-si (KR); Young-soo Park, Yongin-si (KR); Sang-Jin Park, Yongin-si (KR); Sang-min Shin, Yongin-si (KR); Hyuck Lim, Yongin-si (KR); Jung-hoon Shin, Yongin-si (KR)

Correspondence Address: HARNESS, DICKEY & PIERCE, P.L.C., P.O. BOX 8910, RESTON, VA, 20195, US

(21) Appl. No.: 11/812,275

(22) Filed: Jun. 18, 2007

(30) Foreign Application Priority Data
Jun. 16, 2006 (KR) 10-2006-0054531

(51) Int. Cl. H01L 21/336; H01L 21/36

(52) U.S. Cl. 438/301; 438/486; 257/E21.461; 257/E21.409

(57) ABSTRACT

Provided are methods of forming nano crystals and method of manufacturing a memory device suing the same. In an example embodiment, a method of forming nano crystals may include forming an amorphous film on a substrate and converting the amorphous film into an oxide film having the nano crystals by annealing the amorphous film under oxidizing conditions under which part of the crystallized film is oxidized.

### PRIORITY CLAIM

A claim of priority is made under 35 U.S.C. 119, to Korean Patent Application No. 10-2006-0054531, filed on Jun. 16, 2006, in the Korean Intellectual Property Office, the disclosure of which incorporated herein in its entirety by reference.

### BACKGROUND

1. Field

Example embodiments may relate to a material layer in a semiconductor device, a method of manufacturing a semiconductor device having the same, and more particularly, to a method of forming silicon nano crystals and a method of manufacturing a memory device having the same.

2. Description of the Related Art

In general, silicon nano crystals may be manufactured by annealing a silicon rich oxide film at a high temperature to form silicon dots. Silicon nano crystals may also be manufactured by a direct growth method, for example, chemical vapor deposition (CVD) or a silicon ion implantation.

However, when a silicon rich oxide film is annealed at a high temperature to form silicon nano crystals, silicon (Si) diffusion may deteriorate a tunneling oxide film. When a CVD method is used to for silicon nano crystals, it may be difficult to form silicon dots having a uniform size; it may also be difficult to adjust the density of silicon dots, the silicon dots may be formed in a hemispherical shape, and the retention tends to be reduced. In addition, when an ion implantation method is used to form silicon nano crystals, an oxide film may be damaged, and it may be difficult to adjust a doping profile.

### SUMMARY

Example embodiments may provide a method of forming silicon nano crystals.

In an example embodiment, a method of forming nano crystals may include forming an amorphous film on a substrate, and converting the amorphous film into an oxide film having the nano crystals by annealing the amorphous film under oxidizing conditions under which part of the crystallized film is oxidized.

In another example embodiment, a method of manufacturing a memory device having a gate stack structure may include sequentially forming a tunneling film and an amorphous film on a substrate, and converting the amorphous film into an oxide film having the nano crystals by annealing the amorphous film under oxidizing conditions under which part of the crystallized film is oxidized. The method may further include forming a gate structure on the oxide film having the nano crystals, and ion-implanting impurities into the substrate to form source and drain regions using the gate structure as an ion-implanting mask.

### BRIEF DESCRIPTION OF THE DRAWINGS

Example embodiments may become more apparent with reference to the detail description and with reference to the attached drawings in which:

FIGS. 1 and 2 are cross-sectional view illustrating a method of forming silicon nano crystals according to an example embodiment;

FIGS. 3 through 6 are cross-sectional view illustrating a method of manufacturing a memory device using the method illustrated in FIGS. 1 and 2; and

FIG. 7 is a graph illustrating operation characteristics of the memory device of FIG. 6.

### DETAILED DESCRIPTION OF EXAMPLE EMBODIMENTS

Example embodiments will now be described with reference to the accompanying drawings.

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there may be no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-section illustrations that may be schematic illustrations of idealized embodiments (and intermediate structures). As such, variations from the shapes of the illustrations as a result, for example, of manufacturing techniques and/or tolerances, are to be expected. Thus, the example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to limit the example embodiments.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

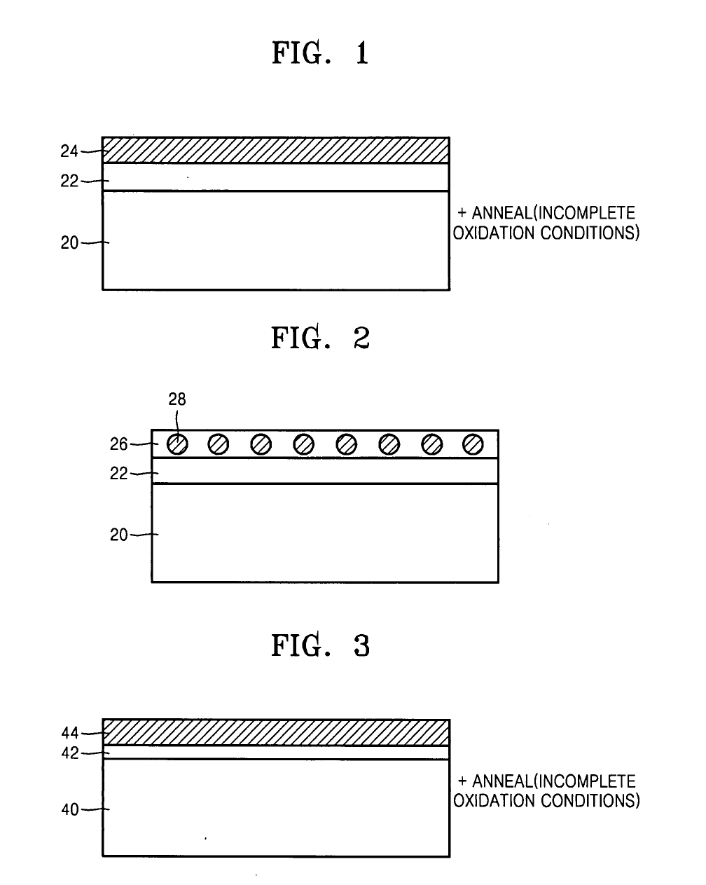

A method of forming silicon nano crystals will be described with reference to FIGS. 1 and 2.

Referring to FIG. 1, an oxide film 22 may be formed on a substrate 20. Then an amorphous film 24 for forming nano crystals may be formed on the oxide film 22. The substrate 20 may be a semiconductor substrate, for example, a p-type substrate. The oxide film 22 may be formed of a silicon oxide (SiO₂). The amorphous film 24 may be an amorphous silicon film. The amorphous film 24 may be formed to a thickness of 1.5 nm to 2.5 nm, for example, 2 nm. The amorphous film 24 may be formed using atomic layer deposition (ALD) or ion beam deposition (IBD). After the amorphous film 24 is formed, the amorphous film 24 may be annealed under incomplete oxidation conditions. In other words, the conditions that do not completely anneal (oxidizes) the amorphous film 24. For example, an annealing process may be performed at about 900° C. for about 2-3 minutes in a gas atmosphere of about 90% nitrogen (N₂) and about 10% oxygen (O₂).

During the annealing process of the example embodiment, the amorphous film 24 may become a crystalline film. Oxidation of the crystalline film may be primarily performed along a grain boundary of the crystalline film. Therefore, oxidation may gradually proceed from the grain boundary towards the inner portion of the crystalline film. In example embodiments, the oxidation conditions, e.g., annealing process, may not crystallize a central region of the crystalline film.

Accordingly, the amorphous film 24 illustrated in FIG. 1 may change into an oxide film 26 having a plurality of nano crystals 28, for example, nano dots, as illustrated in FIG. 2. The amorphous film 24 may be an amorphous silicon film. Thus, the nano crystals 28 may be silicon crystals and the oxide film 26 may be a silicon oxide film. The annealing process may be a process for oxidizing the amorphous film 24, and therefore, silicon may not diffuse into the oxide film 22 during the annealing process. Thus, deterioration of the oxide film 22 during the annealing process may be reduced and/or prevented. The size and distribution density of the nano crystals 28 may be uniformly formed by adjusting the annealing process conditions, for example, adjusting one of the gas atmosphere, time, and temperature. The uniformity of the nano crystals may also be adjusted by varying the thickness of the amorphous film 24. In addition, as illustrated in FIG. 2, the nano crystals 28 may be formed in a circular shape surrounded by the oxide film 26. Thus, when the nano crystals 28 are used as a trap layer in a memory device, retention characteristics of the memory device may be improved.

In example embodiments, when an amorphous film (for example, a silicon film) reacts with oxygen to form a silicon oxide film, a volume of the silicon oxide film may be greater than that of the amorphous film. In example embodiments, a thickness of the silicon oxide film may also be greater than that of the amorphous film.

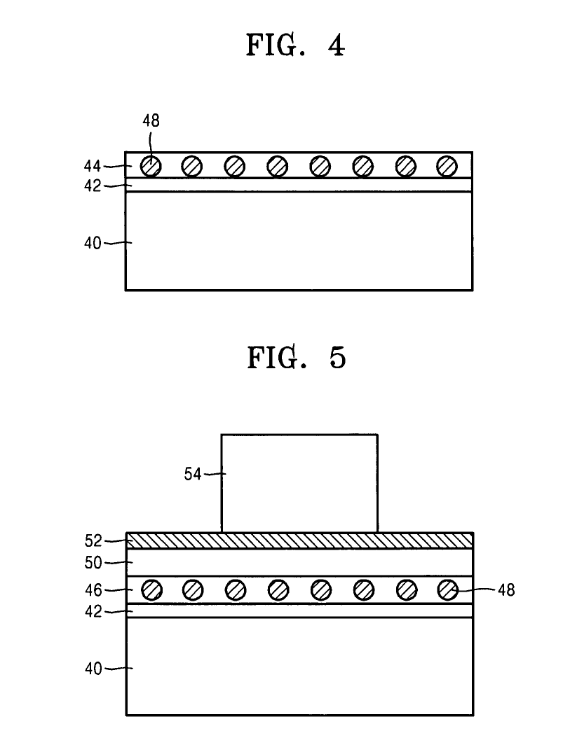

FIGS. 3 through 6 illustrate a method of manufacturing a memory device using the above-described method of forming nano crystals.

Referring to FIG. 3, a tunneling film 42 and an amorphous film 44 may be sequentially formed on a substrate 40. The substrate 40 may be a p-type semiconductor substrate. The tunneling film 42 and the amorphous film 44 may be the oxide film 22 and the amorphous film 24, respectively, illustrated in FIG. 1. After the formation of the amorphous film 44, the amorphous film 44 may be annealed under incomplete oxidation conditions. The annealing process may be the annealing process discussed above with respect to FIGS. 1 and 2. The amorphous film 44 may be changed into an oxide film 46 by the annealing process, as illustrated in FIG. 4. Nano crystals 48 having a uniform size may be formed within the oxide film 46 having a uniform distribution density. The nano crystals 48 may be silicon nano crystals.

Referring to FIG. 5, a shielding film 50 and an electrode layer 52 may be sequentially stacked on the oxide film 46 including the nano crystals 48. A photosensitive film pattern 54 for defining a region for a gate stack structure S1 (FIG. 6) may be formed on the electrode layer 52. The shielding film 50 may reduce and/or prevent electrons from migrating to the electrode layer 52 while carriers, for example, electrons are trapped in the nano crystals 48. The shielding film 50 may be formed of hafnium oxide (HfOx). The shielding film 50 may be formed to a thickness of about 20 nm. The shielding film 50 may be an insulating film not including an oxide film. The electrode layer 52 may be a metallic layer or a metallic silicide layer. Subsequently, stack structures 42, 46, 50, and 52 on the substrate 40 may be sequentially etched using the photosensitive film pattern 54 as an etch mask to expose the substrate 40. After the etching, the photosensitive film pattern 54 may be removed. As a result, a gate stack structure S1 including the tunneling film 42, the oxide film 46 having the nano crystals 48, the shielding film 50, and the electrode layer 52 may be formed in a desired region of the substrate 40, as illustrated in FIG. 6.

Conductive impurities may be ion-implanted into the substrate 40 using the gate stack structure S1 as a mask, thereby forming a source region 60 and a drain region 70. A nonvolatile memory device having a trap layer, for example, the nano crystals 48, in the gate stack structure S1 may be formed. The conductive impurities may be n-type impurities and/or may be opposite to the substrate 40, for example, a p-type substrate.

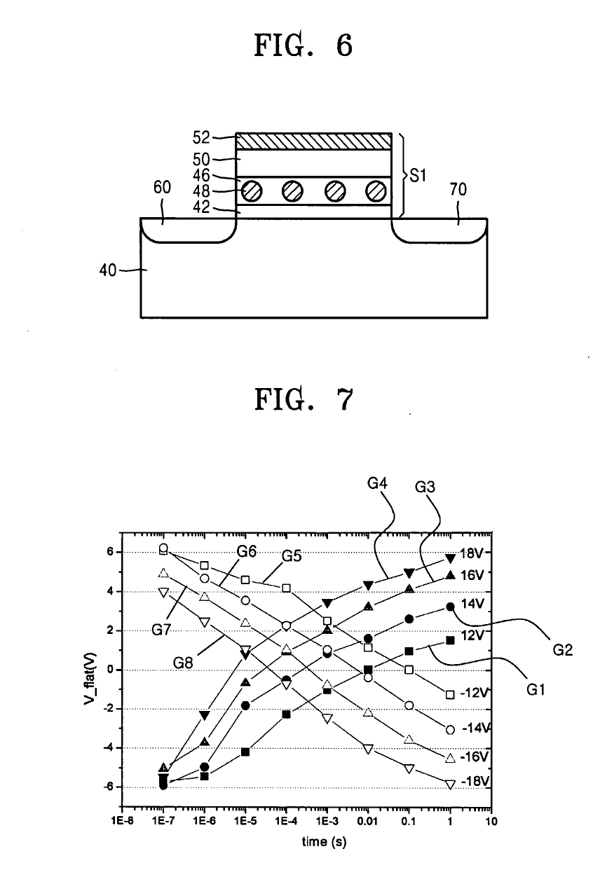

FIG. 7 illustrates write and erasing operation characteristics of the memory device manufactured according to the method illustrated in FIGS. 3-6.

The operation characteristics as illustrated in FIG. 7 were measured for a memory device having a tunneling film 42, an oxide film 46 including nano crystals 48, a shielding film 50 having a thickness of 5 nm, a silicon oxide film having a thickness of 3.5 nm including silicon nano crystals, and a hafnium oxide film having a thickness of 20 nm.

In FIG. 7, first through fourth graphs G1-G4 represent write operation characteristics and fifth through eighth graphs G5-G8 represent erase operation characteristics. The first through fourth graphs G1-G4 show variations in flat band voltages according to an applied time when write voltages are 12V, 14V, 16V, and 18V, respectively. The fifth through eighth graphs G5-G8 show variations in flat band voltages according to an applied time when erase voltages are −12V, −14V, −16V, and −18V, respectively.

In the first through fourth graphs G1-G4, flat band voltages increased as a write voltage-applying time increased, and when write voltages are different, flat band voltages are different. This means that when write voltages with different values are applied to the memory device manufactured according to example embodiments, the memory device has different states with respect to respective write voltages. For example, when four different write voltages having different values are applied to the memory device manufactured according to example embodiments, all of the four states of the memory device were different. The four different states of the memory device may be regarded as states in which data 00, 01, 10, and 11 are respectively written, and therefore, it may be regarded that 2-bit data was written.

In the fifth through eighth graphs G5-G8, flat band voltages decreased as an erase voltage time increased, and flat band voltages are different according to respective erase voltages. The fifth through eighth graphs G5-G8 correspond to the first through fourth graphs G1-G4, respectively.

While many matters have been described in the above description, they should be construed as examples embodiments and not for purposes of limitation. For example, other conditions than the above-described incomplete oxidation conditions may be found suitable to those skilled in the art. In addition, an amorphous film 24 may also be formed using other deposition methods other than ALD or IBD. Therefore, it will be understood by those skilled in the art that various changes in form and details may be made therein without departing from scope of the example embodiments as defined by the following claims.

As described above, in the method of forming silicon nano crystals according to the present invention, an amorphous silicon film is annealed under incomplete oxidation conditions. Thus, damage to an oxide film (a tunneling film) caused by diffused silicon may be reduced and/or prevented. Silicon nano crystals having a uniform size and a uniform distribution density may be obtained. Memory devices having the silicon nano crystal trap layer manufactured according to the example embodiments may have flat band voltages which may be discriminated according to write voltages so that multi-bit data may be stored and a memory window may be increased to about 6 V (−3.5 to 2.5 V).

What is claimed is:

1. A method of forming nano crystals comprising:
forming an amorphous film on a substrate; and
converting the amorphous film into an oxide film having the nano crystals by annealing the amorphous film under oxidizing conditions under which part of the crystallized film is oxidized.

2. The method of claim 1, wherein the amorphous film is formed to a thickness of about 1.5 to 2.5 nm.

3. The method of claim 2, wherein the amorphous film is formed to a thickness of about 2.0 nm.

4. The method of claim 1, wherein the amorphous film is an amorphous silicon film.

5. The method of claim 1, wherein the oxidizing conditions include annealing the amorphous film at a temperature of about 900° C. for about 2-3 minutes in a gas atmosphere of about 90% nitrogen (N₂) and about 10% oxygen (O₂).

6. The method of claim 1, wherein the amorphous film is formed by an atomic layer deposition (ALD) method.

7. The method of claim 1, wherein the amorphous film is formed by an ion beam deposition (IBD) method.

8. The method of claim 1, wherein the annealing crystallizes the amorphous film and oxidizes a grain boundary of the crystallized film but does not oxidize a central portion of the inside of the grain boundary of the crystallized film to form the nano crystals.

9. A method of manufacturing a memory device having a gate stack structure comprising:
sequentially forming a tunneling film and an amorphous film on a substrate;
converting the amorphous film into an oxide film having the nano crystals by annealing the amorphous film under oxidizing conditions under which part of the crystallized film is oxidized;
forming a gate structure on the oxide film having the nano crystals; and
ion-implanting impurities into the substrate to form source and drain regions using the gate structure as an ion-implanting mask.

10. The method of claim 9, wherein the amorphous film is formed to a thickness of about 1.5 to 2.5 nm.

11. The method of claim 10, wherein the amorphous film is formed to a thickness of about 2.0 nm.

12. The method of claim 9, wherein the amorphous film is an amorphous silicon film.

13. The method of claim 9, wherein the oxidizing conditions include annealing the amorphous film at a temperature of about 900° C. for about 2-3 minutes in a gas atmosphere of about 90% nitrogen (N₂) and about 10% oxygen (O₂).

14. The method of claim 9, wherein the amorphous film is formed by an atomic layer deposition (ALD) method.

15. The method of claim 9, wherein the amorphous film is formed by an ion beam deposition (IBD) method.

16. The method of claim 9, wherein forming the gate structure comprises:
sequentially forming a shielding layer and an electrode layer on the oxide film having the nano crystals;
forming a photosensitive film pattern on the electrode layer;
etching the shielding layer, electrode layer, and the oxide film having the nano crystals using the photosensitive film pattern as an etch mask; and
removing the photosensitive film layer.

17. The method of claim 16, wherein the shielding layer is hafnium oxide, and the electrode layer on a metallic layer or a silicide layer.

18. The method of claim 16, wherein the shielding layer is formed to a thickness of about 20 nm.

19. The method of claim 9, wherein the impurities implanted into the substrate are N-type impurities and the substrate is p-type substrate.

20. The method of claim 9, wherein the annealing crystallizes the amorphous film and oxidizes a grain boundary of the crystallized film but does not oxidize a central portion of the inside of the grain boundary of the crystallized film to form the nano crystals.
